(19) United States
(12) Patent Application Publication
(10) Pub. No.: US 2009/0032843 A1
(43) Pub. Date: Feb. 5, 2009

(54) SEMICONDUCTOR DEVICE AND METHOD FOR MANUFACTURING THE SAME

(76) Inventors: Atsushi OHTA, Yokohama-shi (JP); Gaku Sudo, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/179,384

(22) Filed: Jul. 24, 2008

(30) Foreign Application Priority Data
Jul. 27, 2007 (JP) 2007-196627

(51) Int. Cl. H01L 27/092; H01L 21/8238

(52) U.S. Cl. 257/190; 438/218; 257/E27.062; 257/E21.632

(57) ABSTRACT

A semiconductor device includes a semiconductor substrate, and a MIS type FET provided on the semiconductor substrate, the MIS type FET includes a gate insulating film provide on the semiconductor substrate, a gate electrode provided on the gate insulating film, a channel region provided in the semiconductor substrate and being isolated from the gate electrode by the gate insulating film, source/drain layers sandwiching the channel region, the source/drain layers including semiconductor layers having lattice spacing which is different from that of the semiconductor substrate and having uniform height, and a metal silicide layer provided on a region including a top surfaces of the source/drain layers and failing to provide on the channel region.

### CROSS-REFERENCE TO RELATED APPLICATIONS

This application is based upon and claims the benefit of priority from prior Japanese Patent Application No. 2007-196627, filed Jul. 27, 2007, the entire contents of which are incorporated herein by reference.

### BACKGROUND OF THE INVENTION

1. Field of the Invention

The present invention relates to a semiconductor device comprising the source/drain layers formed of semiconductor layers having lattice spacing which is different from that of the semiconductor substrate and method for manufacturing the same.

2. Description of the Related Art

Techniques of improving the performance of transistor by applying stress to the channel have been employed since the 90 nm generation. For example, a technique of improving performance of an n-channel FET (nFET) by using a stress liner. In addition, a DSL (dual stress liner) using optimum stress liners respectively in an nFET and a p-channel FET (pFET), or a structure (eSiGe (embedded SiGe)) in which SiGe is embedded in source/drain regions of the pFET is proposed (Jpn. Pat. Appln. Publication No. 2006-261283).

Recently, relating to the nFET and pFET which are formed on the same substrate, an attempt is proposed to fill the trenches formed in the source/drain regions of the nFET with SiC layers and the trenches formed in the source/drain regions of the pFET with SiGe layers on the same substrate. However, a cumbersome process is required for such an attempt.

Since SiC layers and SiGe layers are formed by epitaxial growth, facets are produced in the SiC layers and the SiGe layers. FIGS. 24 and 25 schematically illustrate such the facets. FIG. 25 is a cross-sectional view of a portion shown by broken line in FIG. 24 and viewed from a direction indicated by arrow in FIG. 24. In FIGS. 24 and 25, 400 denotes a silicon substrate, 401 denotes a SiGe or SiC layer, 402 denotes a facet (a crystal surface inclined by a certain angle relative to the surface of the silicon substrate 400), 403 denotes an extension, 404 denotes a gate insulating film, 405 denotes a gate electrode, 407 and 408 denote side walls, and 410 denotes the surface of the silicon substrate 400 at the edge of the facet 402. In addition, 411 denotes an isolation region (STI).

As shown in FIG. 25, the surface 410 of the silicon substrate 400 is exposed at the edges of the facets 402. The SiGe or SiC layer 401 on the surface 410 is thin. Thus when silicidation is performed, the silicidation progresses from the thin SiGe or SiC layer 401 to the substrate surface where is the extension 403. Therefore, as shown in FIG. 26, an abnormal growth of silicide, in which the metal silicide layers 409 invade the channel region beyond the extensions 403, takes place in the silicidation step. The channel length is shorten by the extent of the invasion of the metal silicide layer 409, so that leak current tends to be occurred.

In addition, as shown in FIG. 27, a semiconductor device 501 normally has a plurality of active areas 502a-502d therein. In the active areas 502a-502d, as shown in FIGS. 28A-28D, MIS type FETs having different width of active lay (channel widths) L respectively are formed. In FIGS. 28A-28D, G denotes a gate electrode, S/D denotes a source/drain layer (epitaxial growth layer), SW denotes a side wall, and STI denotes isolation region.

The epitaxial growth conditions of the source/drain layers are normally same even if the widths L are different from each other. Thus, the source/drain layers (epitaxial growth layers) having different widths L have different heights respectively due to the facets. Such the deviation in height enhances the deviation in device characteristics (e.g. drive capacity).

More specifically, when the etching conditions for forming contact holes are determined in conformity with the source/drain layer whose top surface is highest, sufficient contact may not be obtained to the source/drain layer whose top surface is lowest (increasing of contact resistance).

Conversely, when the etching conditions for forming contact holes are determined in conformity with the source/drain layer whose top surface is lowest, the source/drain layer whose top surface is highest may be etched more than necessary (over-etching).

Such the increasing of contact resistance or over-etching enhances the deviation in the device characteristic. This problem may be solved by optimizing the epitaxial growth conditions for each of the source/drain layers having different widths L, but such a solution is not realistic because it requires long time.

### BRIEF SUMMARY OF THE INVENTION

According to an aspect of the present invention, there is provided a semiconductor device comprising: a semiconductor substrate; and a MIS type FET provided on the semiconductor substrate; the MIS type FET comprising a gate insulating film provide on the semiconductor substrate, a gate electrode provided on the gate insulating film, a channel region provided in the semiconductor substrate and being isolated from the gate electrode by the gate insulating film, source/drain layers sandwiching the channel region, the source/drain layers including semiconductor layers having lattice spacing which is different from that of the semiconductor substrate and having uniform height, and a metal silicide layer provided on a region including a top surfaces of the source/drain layers and failing to provide on the channel region.

According to an aspect of the present invention, there is provided a method for manufacturing a semiconductor device comprising a semiconductor substrate and a MIS type FET including a channel region and provided on the semiconductor substrate, the method comprising: forming a first trench and a second trench in a surface of the semiconductor substrate such that the first trench and the second trench sandwich the channel region; filling the first trench and the second trench with a semiconductor layer which is epitaxially grown, the semiconductor layer having lattice spacing which is different from that of the semiconductor substrate; and facets of the semiconductor layer being formed outside the first trench and the second trench; forming source/drain layers comprising the semiconductor layer, the forming the source/drain layers including removing a part of the semiconductor layer, the part being outside the first trench and the second trench, and planarizing the semiconductor layer; and forming an isolation region by etching the semiconductor substrate and the source/drain layers wherein a par of the source/drain layers is removed by the etching such that the source/drain layers have predetermined dimensions.

According to another aspect of the present invention, there is provided a method for manufacturing a semiconductor device comprising a semiconductor substrate and a MIS type FET including a channel region and provided on the semiconductor substrate, the method comprising: forming an insulating film on the semiconductor substrate; forming a first opening and a second opening which penetrate the insulating film and forming a first trench and a second trench in a surface of the semiconductor substrate such that the first trench and the second trench sandwich the channel region wherein the first and second trenches are respectively formed under the first and second openings; filling the first and second openings and the first and second trenches with a semiconductor layer which is epitaxially grown, the semiconductor layer having lattice spacing which is different from that of the semiconductor substrate; and facets of the semiconductor layer being formed outside the first and second openings and the first and second trenches; forming source/drain layers comprising the semiconductor layer, the forming the source/drain layers including removing a part of the semiconductor layer, the part being outside the first and second openings and the first and second trenches, and planarizing the semiconductor layer; forming an isolation region by etching the semiconductor substrate and the source/drain layers wherein a par of the source/drain layers is removed by the etching such that the source/drain layers have predetermined dimensions. removing the insulating film on the channel region; forming a spacer on a sidewall of a concave portion which is formed by removing the insulating film on the channel region wherein the sidewall is a side surface of the semiconductor layer; forming a gate insulating film on a bottom surface of the concave portion; forming a gate electrode on the gate insulating film; removing the spacer; forming extensions by introducing dopant on a surface of the semiconductor substrate wherein the surface is an exposed surface formed by removing the spacer; forming an insulating spacer on a sidewall of the concave portion such that the extensions are covered with the insulating spacer, and a region between the sidewall of the concave portion and side surface of the gate electrode are filled with the insulating spacer; and forming metal silicide layers on regions including top surfaces of the source/drain layers, the forming the metal silicide layers including forming a refractory metal film on a region including the source/drain layers, and reacting the refractory metal film and the source/drain layers each other by heating treatment.

### BRIEF DESCRIPTION OF THE SEVERAL VIEWS OF THE DRAWING

FIG. 1 is a plane view of a semiconductor device in accordance with an embodiment;

FIG. 2 is a cross-sectional view taken along line A-A′ and line B-B′ of FIG. 1;

FIG. 3 is a cross-sectional view showing a process for manufacturing the semiconductor device in accordance with the embodiment;

FIG. 4 is a cross-sectional view showing the process for manufacturing the semiconductor device in accordance with the embodiment following the FIG. 3;

FIG. 5 is a cross-sectional view showing the process for manufacturing the semiconductor device in accordance with the embodiment following the FIG. 4;

FIG. 6 is a cross-sectional view showing the process for manufacturing the semiconductor device in accordance with the embodiment following the FIG. 5;

FIG. 7 is a cross-sectional view showing the process for manufacturing the semiconductor device in accordance with the embodiment following the FIG. 6;

FIG. 8 is a cross-sectional view showing the process for manufacturing the semiconductor device in accordance with the embodiment following the FIG. 7;

FIG. 9 is a cross-sectional view showing the process for manufacturing the semiconductor device in accordance with the embodiment following the FIG. 8;

FIG. 10 is a plain view showing the process for manufacturing the semiconductor device in accordance with the embodiment following the FIG. 9;

FIG. 11 is a plain view showing the process for manufacturing the semiconductor device in accordance with the embodiment following the FIG. 10;

FIG. 12 is a cross-sectional view showing the process for manufacturing the semiconductor device in accordance with the embodiment following the FIG. 11;

FIG. 13 is a cross-sectional view showing the process for manufacturing the semiconductor device in accordance with the embodiment following the FIG. 12;

FIG. 14 is a plain view showing the process for manufacturing the semiconductor device in accordance with the embodiment following the FIG. 13;

FIG. 15 is a cross-sectional view showing the process for manufacturing the semiconductor device in accordance with the embodiment following the FIG. 14;

FIG. 16 is a cross-sectional view showing the process for manufacturing the semiconductor device in accordance with the embodiment following the FIG. 15;

FIG. 17 is a plain view showing the process for manufacturing the semiconductor device in accordance with the embodiment following the FIG. 16;

FIG. 18 is a cross-sectional view showing the process for manufacturing the semiconductor device in accordance with the embodiment following the FIG. 17;

FIG. 19 is a cross-sectional view showing the process for manufacturing the semiconductor device in accordance with the embodiment following the FIG. 18;

FIG. 20 is a cross-sectional view showing the process for manufacturing the semiconductor device in accordance with the embodiment following the FIG. 19;

FIG. 21 is a plain view showing the process for manufacturing the semiconductor device in accordance with the embodiment following the FIG. 20;

FIG. 22 is a cross-sectional view showing the process for manufacturing the semiconductor device in accordance with the embodiment following the FIG. 21;

FIG. 23 is a cross-sectional view showing the process for manufacturing the semiconductor device in accordance with the embodiment following the FIG. 22;

FIG. 24 is a cross-sectional view showing a conventional process for manufacturing a semiconductor device;

FIG. 25 is a cross-sectional view of a portion shown by broken line and viewed from a direction indicated by arrow in FIG. 24;

FIG. 26 is a cross-sectional view showing the conventional process for manufacturing the semiconductor device following the FIG. 24;

FIG. 27 is a cross-sectional view showing active areas in a semiconductor device; and

FIGS. 28A-28D are plane views showing MIS type FETs in the active areas.

### DETAILED DESCRIPTION OF THE INVENTION

Embodiments of the present invention will be described with reference to the accompanying drawings.

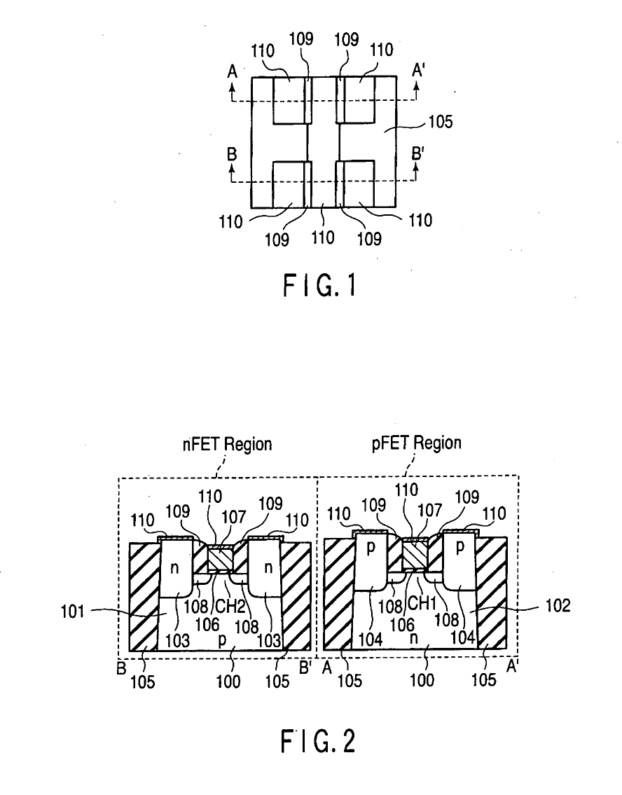

FIG. 1 is a plane view of a semiconductor device in accordance with an embodiment. FIG. 2 is a cross-sectional view taken along line A-A′ and line B-B′ of FIG. 1. The present embodiment will be described in terms of an n-channel MIS FET (nFET) and a p-channel MIS FET (pFET) constituting a CMOS. In FIG. 2, the left region surrounded by broken lines shows an nFET region and the right region surrounded by broken lines shows a pFET region.

The nFET of the present embodiment comprises a silicon substrate 100, a gate insulating film 106 formed on the silicon substrate 100, a gate electrode 107 formed on the gate insulating film 106, a channel region CH1 provided in the silicon substrate 100 and being isolated from the gate electrode 107 by the gate insulating film 106, SiC layers (source/drain layers) 103 which are formed to sandwich the channel region CH1 and have lattice spacing being different from that of the silicon substrate 100 and have the uniform height, a nickel silicide layer (metal silicide layer) 110 formed on a region including the top surface of the SiC layers (source/drain layers) 103 but not formed on the channel region CH1.

On the other hand, the pFET of the present embodiment comprises a silicon substrate 100, a gate insulating film 106 formed on the silicon substrate 100, a gate electrode 107 formed on the gate insulating film 106, a channel region CH2 provided in the silicon substrate 100 and being isolated from the gate electrode 107 by the gate insulating film 106, SiGe layers (source/drain layers) 104 which are formed to sandwich the channel region CH2 and have lattice spacing being different from that of the silicon substrate 100 and have the uniform height, a nickel silicide layer (metal silicide layer) 110 formed on a region including the top surface of the SiGe layers (source/drain layers) 104 but not formed on the channel region CH2.

In the nFET and the pFET of the present embodiment, the metal silicide layers 110 do not invade the channel regions CH1 and CH2, thus the problem that leak current is tend to be occurred does not exist.

The source/drain layers 103, 104 of the nFET and the pFET of the present embodiment have a uniform height. As will be described in detail hereinafter, the semiconductor layer to be processed into the source/drain layers 103, 104 is formed by epitaxial growth. The facets are produced on the semiconductor layer (epitaxial semiconductor layers. The facets are removed by CMP (chemical mechanical polishing) process and the surface of the semiconductor layer is planarized (FIG. 4-FIG. 8). As the surface of the semiconductor layer is planarized, the source/drain layers 103, 104 (epitaxial semiconductor layer) show the uniform height. In this manner, according to the present embodiment, the heights of the source/drain layers 103, 104 are set same, the deviation in device characteristics is suppressed even if the process such as CS processing (processing for forming contact to source) is performed.

In addition, the top surfaces of the source/drain layers 103, 104 of the nFET and the pFET of the present embodiment are higher than the top surfaces of the gate electrodes 107. The source/drain layers 103, 104 comprise first portions filling the trenches formed in the silicon substrate 100 and second portions projecting upward from the trenches. The side surfaces of the source/drain layers 103, 104 are perpendicular or substantially perpendicular relative to the top surfaces of the source/drain layers 103, 104.

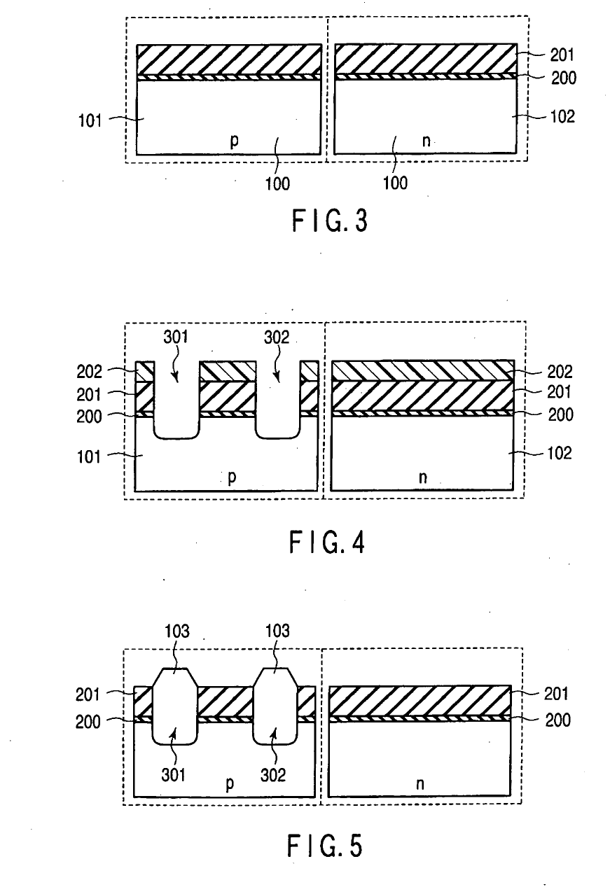

Next, a method of manufacturing the semiconductor device of the present embodiment will be described below by referring to FIG. 3-FIG. 23.

[FIG. 3]

A p-well 101 and an n-well 102 are formed on the surface of a silicon substrate 100, thereafter an oxide film 200 having about 2 nm thickness and a silicon nitride film 201 having about 100 nm thickness are successively formed on the p-well 101 and the n-well 102.

[FIG. 4]

By using a photoresist pattern 202 as a mask, the silicon nitride film 201, the oxide film 200 and the p-well 101 (silicon substrate 100) are etched by RIE (reactive ion etching) process, thereby first and second openings which penetrate the silicon nitride film 201 and the oxide film 200 are formed, further first and second trenches are formed on the surface of the p-well 101 (silicon substrate 100) such that the first and second trenches sandwich the channel region of the nFET wherein the first and second trenches are respectively formed under the first and second openings;

In FIG. 4, both the first opening and the first trench are collectively denoted by a single reference symbol 301. Similarly, the second opening and the second trench are collectively denoted by a single reference symbol 302.

[FIG. 5]

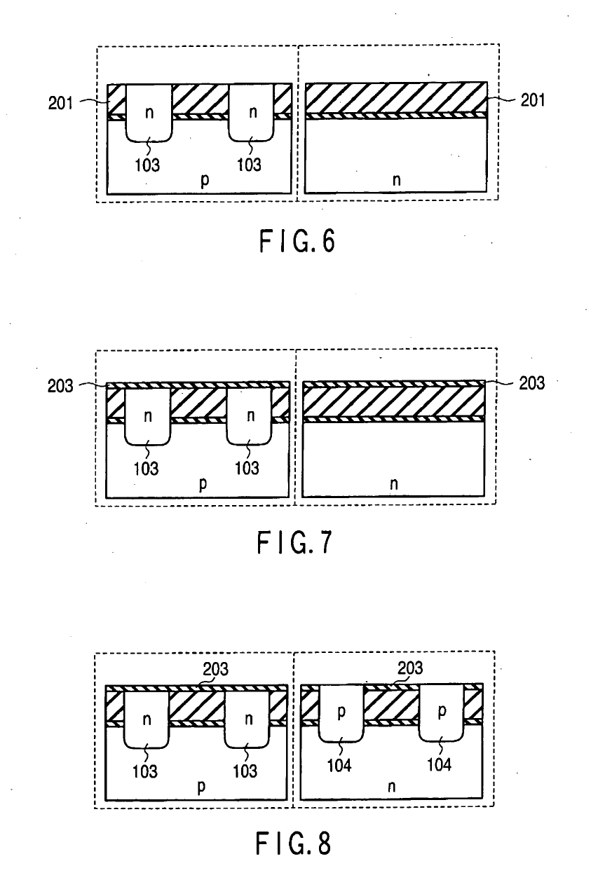

After removing the photoresist pattern 202, SiC layers 103 (epitaxial semiconductor layers) which fill the first opening and first trench 301 and the second opening and second trench 302 are formed by epitaxial growth. The SiC layers 103 are formed so as to overflow the first opening and first trench 301 and the second opening and second trench 302 and facets of the SiC layer 103 are formed on the overflowing portions.

[FIG. 6]

By performing CMP process using the silicon nitride film 201 as a stopper, the SiC layers 103 where facets are formed outside the first opening and first trench 301 and the second opening and second trench 302 are removed by way of a CMP process and the surface of the nFET region is planarized. Thereafter, an n-type dopant is introduced into the SIC layers 103. The n-type dopant is, for example, As, and the method of introducing the dopant is, for example, ion implantation. In this manner, source/drain layers comprising the SiC layers 103 containing n-type dopant are formed in the nFET region.

[FIG. 7]

A silicon nitride film 203 having about 10 nm thickness is formed on the entire surface.

[FIG. 8]

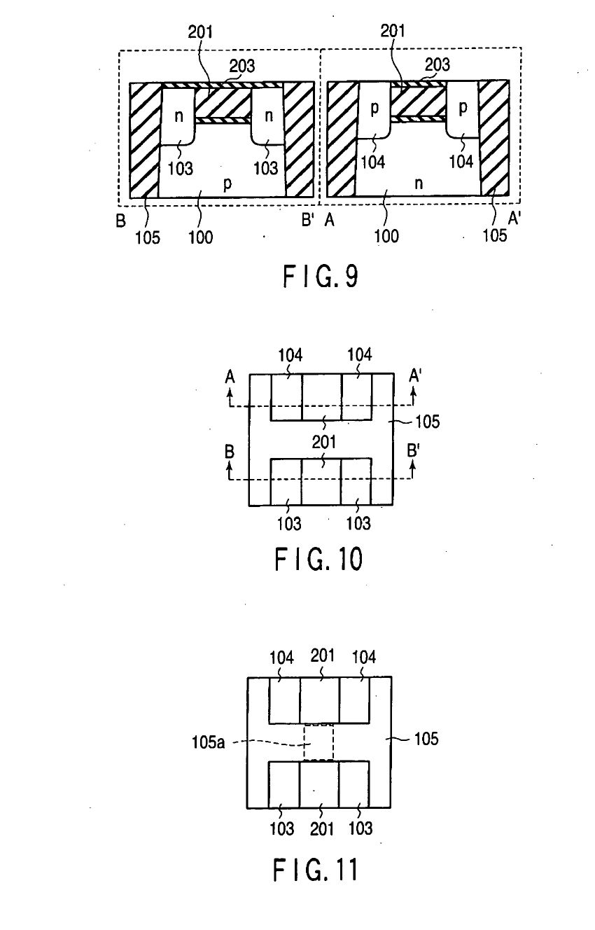

By the technique similar to the FIGS. 4-6, SiGe layers 104 (epitaxial semiconductor layers) are filled in the surface of the n-well 102 and p-type dopant (e.g., B) is introduced into the SiGe layers 104, thereby the source/drain layers of the pFET are formed. In a case of the present embodiment, the top surfaces of the SiGe layers 104 are slightly higher than the top surfaces of the SiC layers 103 by an amount corresponding to the thickness of the silicon nitride film 203.

[FIG. 9, FIG. 10]

an isolation trench having about 300 nm depth is formed on the surface of the substrate 100, the isolation trench is filled with an isolation insulating film (STI process), thereby the isolation regions 105 is formed. Here, a silicon oxide film is used as the isolation insulating film.

At this time, the isolation trench is formed so as to penetrate parts of the SiC layers 103 and the SiGe layers 104 and remove the parts in order to form the source/drain layers (SiC layers 103, SiGe layers 104) having predetermined dimensions. Thereby the following advantages are obtained.

As shown in FIG. 27, FETs having different widths L exist in the semiconductor device. In the conventional method, after forming the isolation region, the trenches corresponding to widths L are formed on the surface of the substrate and the trenches are filled with source/drain layers (epitaxial semiconductor layers) which are epitaxially grown.

At this time, the source/drain layers are formed under the same epitaxial growth conditions even if the widths L are different, thus if the widths L of active regions differ, the heights of source/drain layers differ.

However, according to the present embodiment, source/drain layers having the same dimensions are formed under the same epitaxial growth conditions even if the FETs have different widths L, thereafter the isolation region are formed so that the source/drain layers have the predetermined dimensions, thereby the source/drain layers have the same height even if the widths L of active regions differ. Therefore, according to the present embodiment, the deviation of device characteristic due to the deviation of height of source/drain layers among the active areas having different widths L are suppressed.

The FETs having different widths L in the semiconductor device may be formed at the same time or the FETs having different widths L may be formed separately.

In the conventional technique, the quantity of Ge or C supplied into the trenches varies depending on the width L because the dimensions (opening ratio) of the trenches to be formed on the surface of the substrate vary as a function of the width L. Therefore, when manufacturing products with different device sizes (generations) that are functionally identical, the epitaxial growth conditions need to be optimized for each device size (generation).

However, according to the present embodiment, when manufacturing products (e.g., SRAM, logic IC) with different device sizes (generations), the quantity of Ge or C supplied into the trenches can be made unvaried by forming source/drain layers in trenches having the same dimensions (opening ratio) under the same epitaxial growth conditions and then forming isolation regions so as to make the source/drain layers have the predetermined dimensions. Therefore, according to the present embodiment, the epitaxial growth conditions are not required to be optimized for each device size (generation), and the manufacturing conditions need not to be defined for each product when manufacturing products with different device sizes (generations).

[FIG. 11]

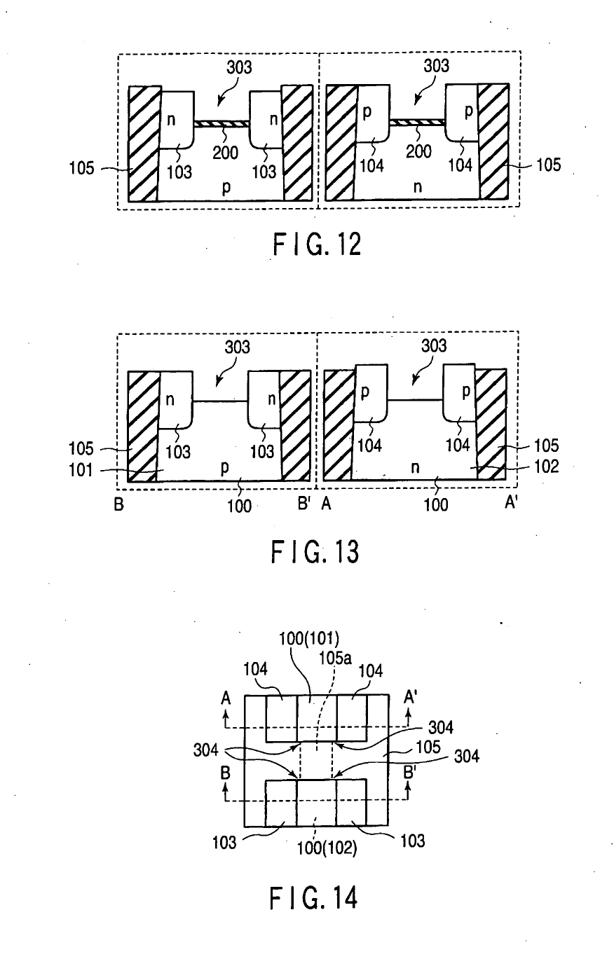

By using a resist pattern (not shown) as a mask, the isolation region 105 (105a) between the nFET and the pFET is selectively etched by RIE process, thereby the height of isolation region 105a is lowered by 10 nm than the height of isolation region 105 which surrounds the isolation region 105a. As a result, gate electrodes which connect the nFET region and the pMOS region electrically are formed in a self-align manner in the step of forming the gate electrodes which is performed later.

[FIG. 12]

The silicon nitride films 201, 203 are selectively removed by wet etching. The etching solution is, for example, hot phosphoric acid solution. As the silicon nitride film 201 is removed, concave portions (trenches) 303 are formed respectively in the gate forming region of the nFET region and that of the pFET region.

[FIG. 13, FIG. 14]

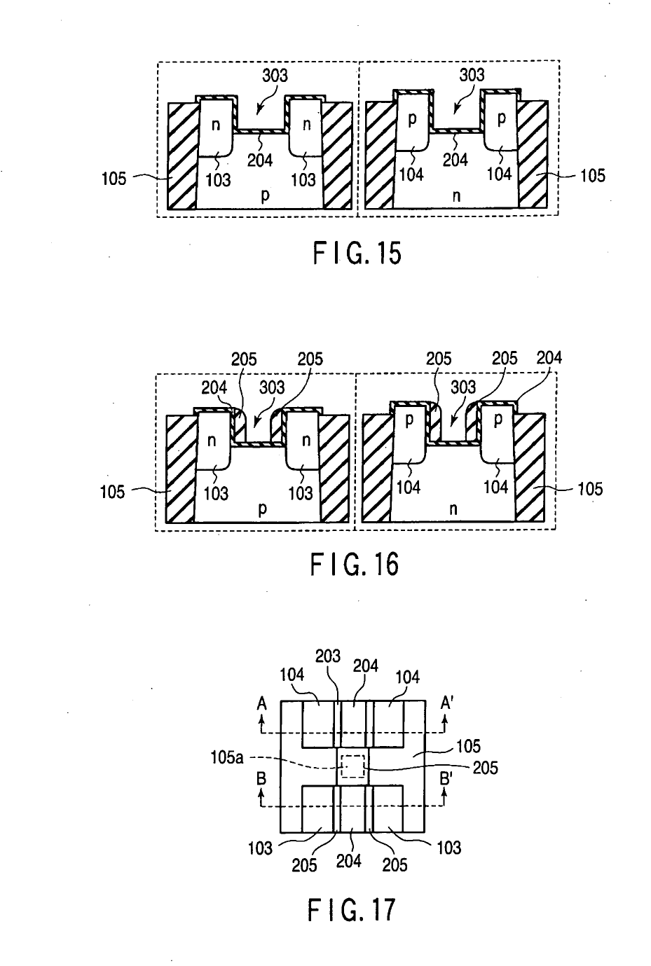

The top surfaces of the isolation regions (silicon oxide films) 105, 105a are lowered by wet etching to expose the upper side surfaces 304 of the silicon substrate 100 (p-well 101, n-well 102), that is, the side surface of silicon substrate which is the boundary with the STI in the channel length direction. Thereby, in the step of forming the gate electrode, gate electrodes are formed also on the exposed upper side surfaces 304 to provide an advantage of raising the drive capacity. The oxide film 200 is also removed by the wet etching.

[FIG. 15]

Silicon oxide films 204 are formed by thermal oxidation on the bottom surfaces of the concave portions 303, that is, on the surfaces (channel regions) of the silicon substrate 100. In this case, the silicon oxide films 204 are also formed on the exposed surfaces (upper surfaces, side surfaces) of the SiC layers 103 and the SiGe layers 104.

[FIG. 16, FIG. 17]

A silicon nitride film to be processed into spacers 205 is deposited on the entire surface, next, this silicon nitride film is etched by RIE process, thereby the spacers 205 are formed on the sidewalls of the SiC layers 103 and the SiGe layers 104.

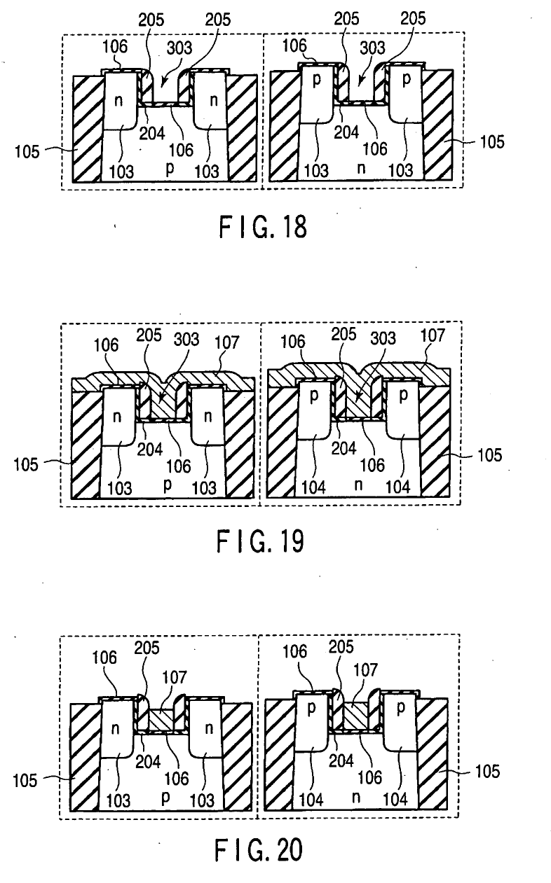

During the RIE process, the surface of the silicon substrate 100 is free from etching damage because the surface of the silicon substrate 100 is covered with the silicon oxide films 204.

[FIG. 18]

The exposed silicon oxide films 204 is selectively removed by wet etching, thereafter a gate insulating films 106 are formed on the surface of the silicon substrate 100. Here, the gate insulating films 106 are thermal oxide films, and the thermal oxide films are also formed on the exposed surfaces of the SiC layers 103 and the SiGe layers 104.

[FIG. 19]

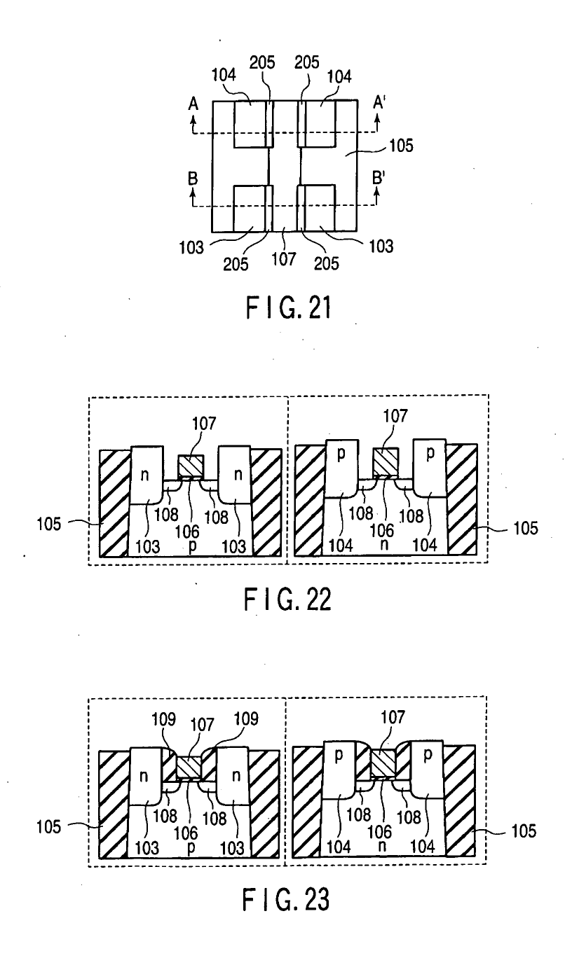

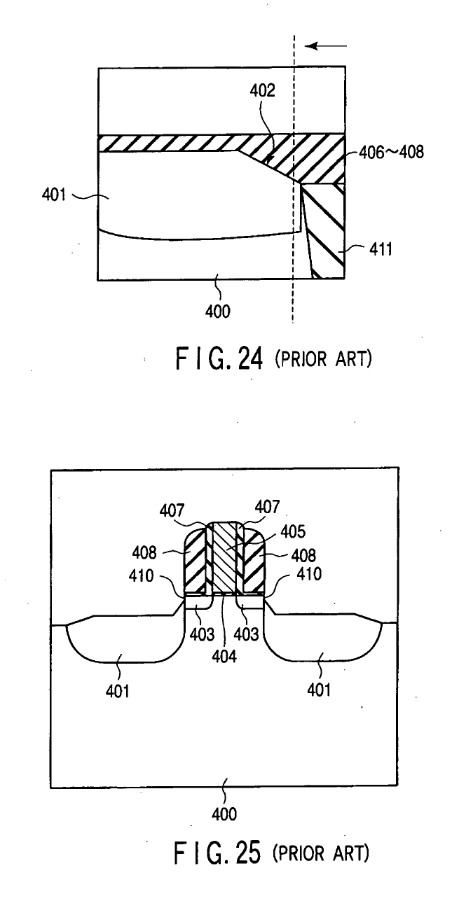

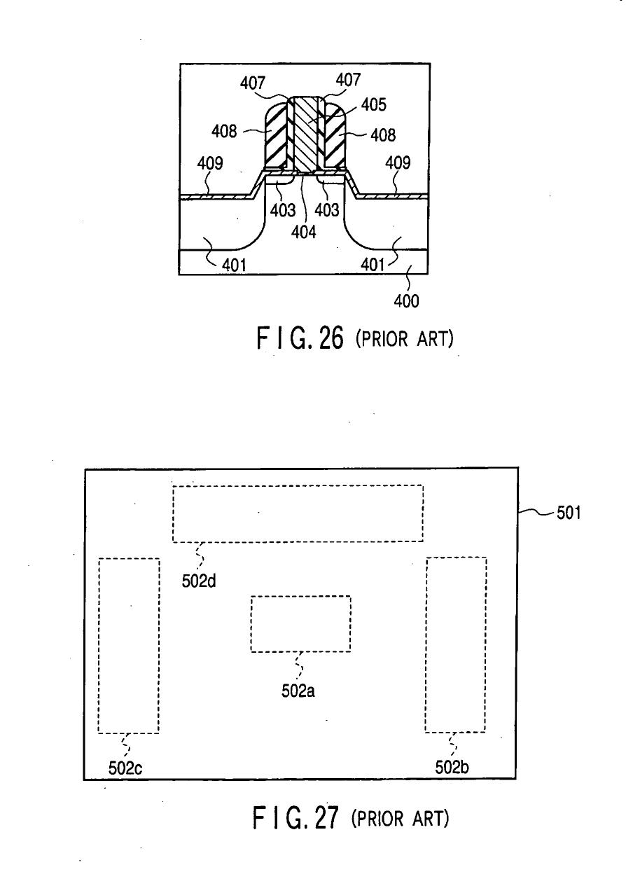

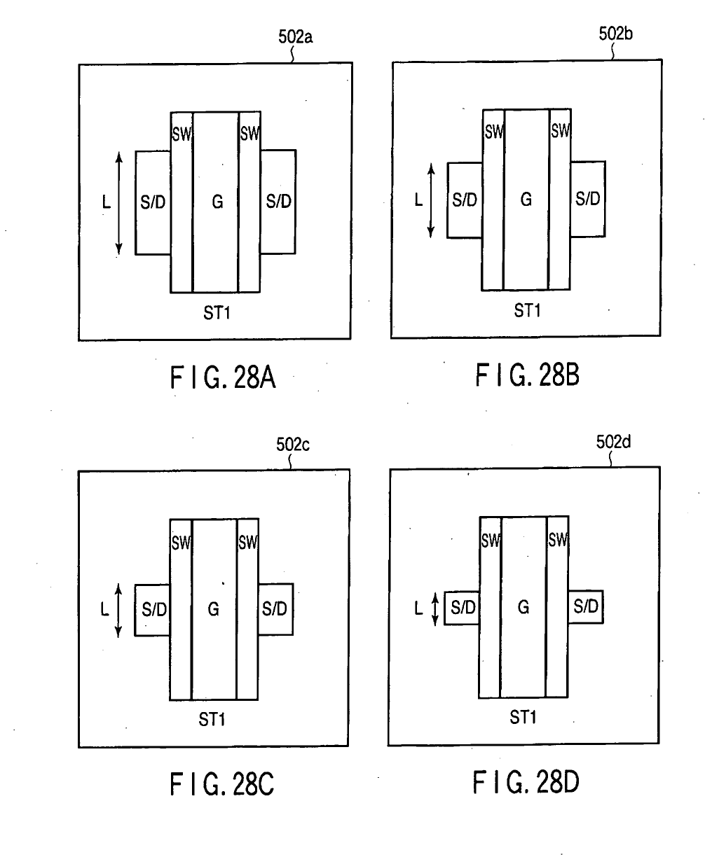

A polycrystalline silicon film 107 to be processed into the gate electrodes is deposited on the entire surface.

[FIG. 20, FIG. 21]

Gate electrodes comprising the polycrystalline silicon film 107 are formed on the gate insulating films 106 in the concave portions by etch-backing the polycrystalline silicon film 107 using RIE process.

At this time, the isolation region 105a that is lower than the surroundings is filled with the polycrystalline silicon film 107. The gate electrode of the nFET and the gate electrode of the pFET are connected by the polycrystalline silicon film 107 in the isolation region 105a. Therefore, according to the present embodiment, as the gate electrodes (polycrystalline silicon film) 107 that electrically connect the nFET region and the pMOS region are formed in a self-aligning manner, the process is simplified.

[FIG. 22]

The spacers 205 and the silicon oxide film 204 are successively removed by wet etching. Extensions 108 are formed by ion implantation and annealing.

The extensions 108 may be formed by ion implantation and annealing without removing the silicon oxide film 204 after removing the spacers 205. In this case, the silicon oxide film 204 is removed after forming the extensions 108.

[FIG. 23]

Spacers (gate sidewall insulating film) 109 are formed by depositing a silicon nitride film and etching the silicon nitride film like the step of forming the spacers 205. The spacers 109 cover the surfaces of the extensions 108 and fill the regions between the SiC layers 103 and the gate electrode 107 and the regions between the SiGe layers 104 and the gate electrode 107. Thereby, the silicon substrate 100 does not show any exposed surface.

Thereafter, a nickel film is deposited on the entire surface, then the nickel film and the gate electrodes (polycrystalline silicon film) 107, the nickel film and the SiC layers 103, the nickel film and the SiGe layers 104 are respectively reacted by heating treatment (silicide reaction) to form nickel silicide layers 110, so that the semiconductor device shown in FIGS. 1 and 2 is obtained.

Here, the nickel film is deposited on the SiC layers 103 and the SiGe layers 104 that do not have any facet but have the flat surface. In addition, when depositing the nickel film, the silicon substrate 100 has neither an exposed surface nor a facet. Therefore, there does not arise any problem that silicide abnormally grows into the silicon substrate 100 to increase the leak current.

It is noted that metal silicide layers other than the nickel silicide layers 110 (e.g., tungsten silicide layers, cobalt silicide layers or platinum silicide layers) may be formed.

In addition, since the polycrystalline silicon film is used as the gate electrodes in the present embodiment, the metal silicide layer is formed also on the gate electrodes, but no metal silicide layer is formed on the gate electrodes when a metal film (metal gate) is used as the gate electrodes.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate; and
a MIS type FET provided on the semiconductor substrate; the MIS type FET comprising a gate insulating film provide on the semiconductor substrate, a gate electrode provided on the gate insulating film, a channel region provided in the semiconductor substrate and being isolated from the gate electrode by the gate insulating film, source/drain layers sandwiching the channel region, the source/drain layers including semiconductor layers having lattice spacing which is different from that of the semiconductor substrate and having uniform height, and a metal silicide layer provided on a region including a top surfaces of the source/drain layers and failing to provide on the channel region.

2. The semiconductor device according to claim 1, wherein the top surfaces of the source/drain layers are higher than a top surface of the gate electrode.

3. The semiconductor device according to claim 1, wherein the source/drain layers comprises first portions filling trenches formed in a surface of the semiconductor device and second portions projecting upward from the trenches.

4. The semiconductor device according to claim 1, wherein the source/drain layers comprises first portions filling trenches formed in a surface of the semiconductor device and second portions projecting upward from the trenches.

5. The semiconductor device according to claim 1, wherein the semiconductor substrate is a silicon substrate, the source/drain layers is a SiGe layer or a SiC layer.

6. The semiconductor device according to claim 2, wherein the semiconductor substrate is a silicon substrate, the source/drain layers is a SiGe layer or a SiC layer.

7. The semiconductor device according to claim 3, wherein the semiconductor substrate is a silicon substrate, the source/drain layers is a SiGe layer or a SiC layer.

8. The semiconductor device according to claim 4, wherein the semiconductor substrate is a silicon substrate, the source/drain layers is a SiGe layer or a SiC layer.

9. The semiconductor device according to claim 1, wherein the MIS type FET is an n-channel MIS type FET or a p-channel MIS type FET of a CMOS.

10. The semiconductor device according to claim 2, wherein the MIS type FET is an n-channel MIS type FET or a p-channel MIS type FET of a CMOS.

11. The semiconductor device according to claim 3, wherein the MIS type FET is an n-channel MIS type FET or a p-channel MIS type FET of a CMOS.

12. The semiconductor device according to claim 4, wherein the MIS type FET is an n-channel MIS type FET or a p-channel MIS type FET of a CMOS.

13. The semiconductor device according to claim 5, wherein the MIS type FET is an n-channel MIS type FET or a p-channel MIS type FET of a CMOS.

14. The semiconductor device according to claim 6, wherein the MIS type FET is an n-channel MIS type FET or a p-channel MIS type FET of a CMOS.

15. The semiconductor device according to claim 7, wherein the MIS type FET is an n-channel MIS type FET or a p-channel MIS type. FET of a CMOS.

16. The semiconductor device according to claim 8, wherein the MIS type FET is an n-channel MIS type FET or a p-channel MIS type FET of a CMOS.

17. A method for manufacturing a semiconductor device comprising a semiconductor substrate and a MIS type FET including a channel region and provided on the semiconductor substrate, the method comprising:
forming a first trench and a second trench in a surface of the semiconductor substrate such that the first trench and the second trench sandwich the channel region;
filling the first trench and the second trench with a semiconductor layer which is epitaxially grown, the semiconductor layer having lattice spacing which is different from that of the semiconductor substrate; and facets of the semiconductor layer being formed outside the first trench and the second trench;
forming source/drain layers comprising the semiconductor layer, the forming the source/drain layers including removing a part of the semiconductor layer, the part being outside the first trench and the second trench, and planarizing the semiconductor layer; and
forming an isolation region by etching the semiconductor substrate and the source/drain layers wherein a par of the source/drain layers is removed by the etching such that the source/drain layers have predetermined dimensions.

18. The method according to claim 17, wherein the MIS type FET is an n-channel MIS type FET or a p-channel MIS type FET of a CMOS.

19. A method for manufacturing a semiconductor device comprising a semiconductor substrate and a MIS type FET including a channel region and provided on the semiconductor substrate, the method comprising:
forming an insulating film on the semiconductor substrate;
forming a first opening and a second opening which penetrate the insulating film and forming a first trench and a second trench in a surface of the semiconductor substrate such that the first trench and the second trench sandwich the channel region wherein the first and second trenches are respectively formed under the first and second openings;
filling the first and second openings and the first and second trenches with a semiconductor layer which is epitaxially grown, the semiconductor layer having lattice spacing which is different from that of the semiconductor substrate; and facets of the semiconductor layer being formed outside the first and second openings and the first and second trenches;
forming source/drain layers comprising the semiconductor layer, the forming the source/drain layers including removing a part of the semiconductor layer, the part being outside the first and second openings and the first and second trenches, and planarizing the semiconductor layer;
forming an isolation region by etching the semiconductor substrate and the source/drain layers wherein a par of the source/drain layers is removed by the etching such that the source/drain layers have predetermined dimensions.
removing the insulating film on the channel region;
forming a spacer on a sidewall of a concave portion which is formed by removing the insulating film on the channel region wherein the sidewall is a side surface of the semiconductor layer;
forming a gate insulating film on a bottom surface of the concave portion;
forming a gate electrode on the gate insulating film;
removing the spacer;
forming extensions by introducing dopant on a surface of the semiconductor substrate wherein the surface is an exposed surface formed by removing the spacer;
forming an insulating spacer on a sidewall of the concave portion such that the extensions are covered with the insulating spacer, and a region between the sidewall of the concave portion and side surface of the gate electrode are filled with the insulating spacer; and
forming metal silicide layers on regions including top surfaces of the source/drain layers, the forming the metal silicide layers including forming a refractory metal film on a region including the source/drain layers, and reacting the refractory metal film and the source/drain layers each other by heating treatment.

20. The method according to claim 19, wherein the MIS type FET is an n-channel MIS type FET or a p-channel MIS type FET of a CMOS.
